(19) United States
(12) Patent Application Publication
(10) Pub. No.: US 2012/0007053 A1
(43) Pub. Date: Jan. 12, 2012

(54) NITRIDE-BASED SEMICONDUCTOR DEVICE AND METHOD FOR MANUFACTURING THE SAME

(75) Inventors: Woo Chul JEON, Gyeonggi-do (KR); Ki Yeol Park, Gyeonggi-do (KR); Jung Hee Lee, Daegu (KR); Young Hwan Park, Seoul (KR)

(73) Assignee: SAMSUNG ELECTRO-MECHANICS CO., LTD.

(21) Appl. No.: 12/917,834

(22) Filed: Nov. 2, 2010

(30) Foreign Application Priority Data
Jul. 7, 2010 (KR) 10-2010-0065422

(51) Int. Cl. H01L 29/15; H01L 21/20

(52) U.S. Cl. 257/28; 438/478; 257/E29.073; 257/E21.09

(57) ABSTRACT

Disclosed herein is a nitride-based semiconductor device. The nitride-based semiconductor device includes a base substrate having a PN junction structure, an epi-growth layer disposed on the base substrate, and an electrode unit disposed on the epi-growth layer.

### CROSS REFERENCE TO RELATED APPLICATION

This application claims the benefit of Korean Patent Application No. 10-2010-0065422, filed on Jul. 7, 2010, entitled “Nitride-Based Semiconductor Device And Method For Manufacturing The Same”, which is hereby incorporated by reference in its entirety into this application.

### BACKGROUND OF THE INVENTION

1. Technical Field

The present invention relates to a nitride-based semiconductor device and a method for manufacturing the same, and more particularly, to a nitride-based semiconductor device reducing reverse leakage current and a method for manufacturing the same.

2. Description of the Related Art

In general, a III-nitride-based semiconductor including group III elements such as gallium (Ga), aluminum (Al), indium (In), or the like, and nitrogen (N) has characteristics such as a wide energy band gap, high electron mobility and saturation electron velocity, high thermal chemical stability, and the like. A nitride-based field effect transistor (N-FET) based on the III-nitride-based semiconductor is manufactured based on a semiconductor material having a wide energy band gap, for example, a material such as gallium nitride (GaN), aluminum gallium nitride (AlGaN), indium gallium nitride (InGaN), aluminum indium gallium nitride (AlInGaN), or the like.

A general nitride-based field effect transistor includes a base substrate, an epi-growth layer formed on the base substrate, and a Schottky electrode and an ohmic electrode disposed on the epi-growth layer. The nitride-based semiconductor device is formed with a 2-dimensional electron gas (2DEG) generated in the epi-growth layer, which is used as a moving path of current. The nitride-based semiconductor device may perform forward and reverse operations by using the 2-dimensional electron gas as a carrier moving path.

Among the nitride-based semiconductor devices, a device having a Schottky diode structure is a device using a Schottky junction between a metal and a semiconductor. The nitride-based semiconductor device can be switched at a high rate and be driven at a low forward voltage. Generally, a nitride-based semiconductor device such as a Schottky diode has a Schottky electrode forming a Schottky contact as an anode electrode and has an ohmic electrode forming an ohmic contact as a cathode electrode.

However, the Schottky diode having the structure as described above generates leakage current from the Schottky electrode to the base substrate at the time of reverse operation of the device. In order to block the reverse leakage current, a silicon substrate, a silicon carbide substrate, a spinel substrate, and a sapphire substrate having a resistance value of approximate 1 k ohm or more are used as a base substrate of a general nitride-based semiconductor device. However, even though the substrates having a high resistance value are used, it is impossible to basically block the generation of the current leakage. In addition, the substrates having a high resistance value are relatively expensive. In particular, a silicon wafer having a high resistance value of 1 k ohm or more, which is generally and widely used, is remarkably expensive as compared to other substrates, such that it becomes a factor to increase manufacturing costs of the nitride-based semiconductor device.

### SUMMARY OF THE INVENTION

An object of the present invention is to provide a nitride-based semiconductor device blocking reverse leakage current.

Another object of the present invention is to provide a nitride-based semiconductor device with reduced manufacturing costs.

Another object of the present invention is to provide a method for manufacturing a nitride-based semiconductor device blocking reverse leakage current.

Another object of the present invention is to provide a method for manufacturing a nitride-based semiconductor device with reduced manufacturing costs.

According to an exemplary embodiment of the present invention, there is provided a nitride-based semiconductor device, including: a base substrate having a PN junction structure; an epi-growth layer disposed on the base substrate; and an electrode unit disposed on the epi-growth layer.

The PN junction structure may include: a first type of semiconductor substrate; and a second type of impurity doped layer formed by doping an upper portion of the semiconductor substrate with second type of impurity ions.

The first type may be an N-type and the second type may be a P-type.

The semiconductor substrate may be a silicon substrate having resistance value below 1 k ohm, and the base substrate may have a resistance value of 1 k ohm or more.

The PN junction structure may be used as a diode that blocks current from flowing from the electrode unit to the base substrate at the time of reverse operation of the nitride-based semiconductor device.

The base substrate may further include: a buffer layer that is interposed between the base substrate and the epi-growth layer, wherein the buffer layer may include a super-lattice layer.

The super-lattice layer may be formed by alternately stacking an insulator layer and a semiconductor layer.

The epi-growth layer may include: a first nitride layer disposed on the base substrate; and a second nitride layer disposed on the first nitride layer and having a wider energy band gap than the first nitride layer, wherein a 2-dimensional electron gas (2DEG) may be generated between the first nitride layer and the second nitride layer.

The electrode unit may include: a Schottky electrode disposed in the center of the upper portion of the epi-growth layer to form a Schottky contact with the epi-growth layer; a first ohmic electrode disposed at the edge of the upper portion of the epi-growth layer to form an ohmic contact with the epi-growth layer; and a second ohmic electrode covering a lower surface of the base substrate.

According to another embodiment of the present invention, there is provided a method for manufacturing a nitride-based semiconductor device, including: preparing a base substrate having a PN junction structure; forming an epi-growth layer on the base substrate by using the base substrate as a seed layer; and forming an electrode unit on the epi-growth layer.

The preparing the base substrate may include: preparing a first type of semiconductor substrate; and doping an upper portion of the semiconductor substrate opposite to the epi-growth layer with second type of impurity ions.

The first type may be an N-type and the second type may be a P-type.

The preparing the semiconductor substrate may include preparing a silicon substrate having a resistance value below 1 k ohm, and the preparing the base substrate may include a PN junction structure having a resistance value of 1 k ohm or more.

The PN junction structure may be used as a diode that blocks current from flowing from the electrode unit to the base substrate at the time of reverse operation of the nitride-based semiconductor device.

The forming the epi-growth layer may include: growing a first nitride layer on the base substrate by using the base substrate as a seed layer; and growing a second nitride layer having a wider energy band gap than the first nitride layer on the first nitride layer by using the first nitride layer as a seed layer, wherein a 2-dimensional electron gas (2DEG) may be generated between the first nitride layer and the second nitride layer.

The forming the electrode unit may include: forming a Schottky electrode in the center of the upper portion of the epi-growth layer; forming a first ohmic electrode spaced apart from the Schottky electrode at the edge of the upper portion of the epi-growth layer; and forming a second ohmic electrode covering a lower surface of the base substrate.

### BRIEF DESCRIPTION OF THE DRAWINGS

FIG. 1 is a circuit view showing a nitride-based semiconductor device according to an embodiment of the present invention;

FIG. 2 is a side view showing a nitride-based semiconductor device according to an embodiment of the present invention;

FIG. 3 is a flow chart showing a method for manufacturing a nitride-based semiconductor device according to an embodiment of the present invention; and

FIGS. 4 to 6 are diagrams for explaining a process for manufacturing a nitride-based semiconductor device according to an embodiment of the present invention.

### DESCRIPTION OF THE PREFERRED EMBODIMENTS

Various advantages and features of the present invention and methods accomplishing thereof will become apparent from the following description of embodiments with reference to the accompanying drawings. However, the present invention may be modified in many different forms and it should not be limited to the embodiments set forth herein. Rather, these embodiments may be provided so that this disclosure will be thorough and complete, and will fully convey the scope of the invention to those skilled in the art. Like reference numerals in the drawings denote like elements.

Terms used in the present specification are for explaining the embodiments rather than limiting the present invention. Unless explicitly described to the contrary, a singular form includes a plural form in the present specification. The word “comprise” and variations such as “comprises” or “comprising,” will be understood to imply the inclusion of stated constituents, steps, operations and/or elements but not the exclusion of any other constituents, steps, operations and/or elements.

Hereinafter, a nitride-based semiconductor device and a method for manufacturing the same according to an embodiment of the present invention will be described in detail with reference to the accompanying drawings.

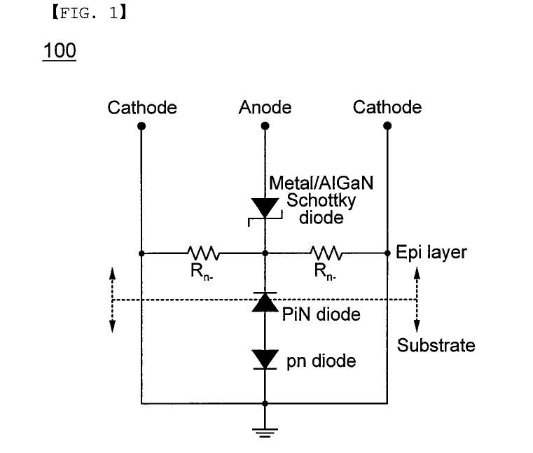

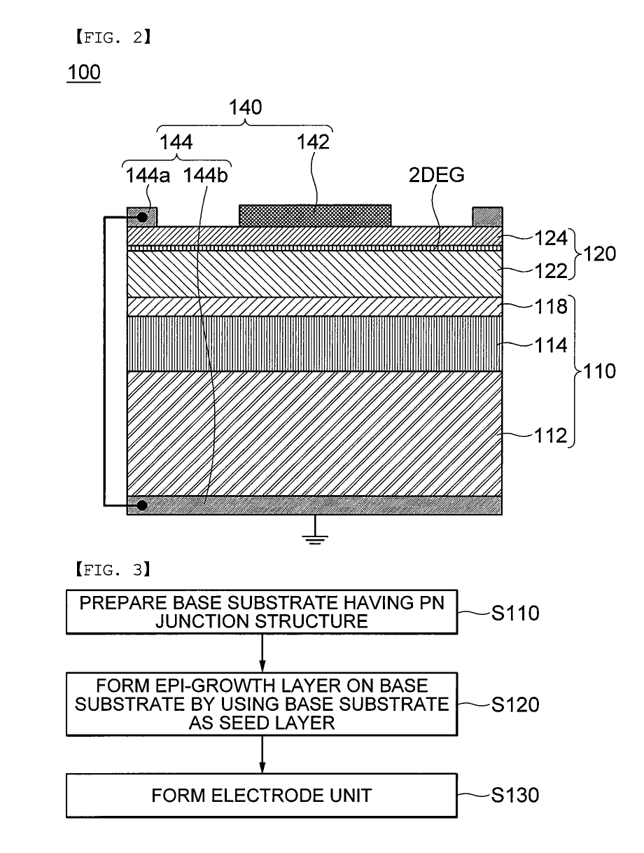

FIG. 1 is a circuit view showing a nitride-based semiconductor device according to an embodiment of the present invention, and FIG. 2 is a side view showing a nitride-based semiconductor device according to an embodiment of the present invention.

Referring to FIGS. 1 and 2, a nitride-based semiconductor device 100 according to an embodiment of the present invention may be a power device having a Schottky barrier diode (SBD) structure. For example, the nitride-based semiconductor device 100 may include a base substrate 110, an epi-growth layer 120, and an electrode unit 140.

The base substrate 110 may be a plate for forming a nitride-based semiconductor device having a high electron mobility transistor (hereinafter, referred to as ‘HEMT’) structure. The base substrate 110 may have a PN junction structure. For example, the base substrate 110 may have a structure in which a first type of semiconductor layer 112 and a second type of semiconductor layer 114 are vertically bonded to each other. As an example, the first type may be an N-type and a second type may be a P-type. The PN junction structure may be formed by implanting P-type semiconductor impurity ions into an upper portion of the first type of semiconductor layer (hereinafter, referred to as N-type semiconductor layer: 112) and then forming the second type of semiconductor layer (hereinafter, referred to as a P-type semiconductor layer: 114) on the N-type semiconductor layer 112. Alternatively, the PN junction structure may be formed by growing the P-type semiconductor layer 114 on the N-type semiconductor layer 112 by using the N-type semiconductor layer 112 as a seed layer. Herein, as the base substrate 110, a substrate having a relatively low resistance value may be used. In other words, as the N-type semiconductor substrate, a silicon substrate having a low resistance value below 1 k ohm may be used. A process of manufacturing the base substrate 110 will be described in detail below.

Meanwhile, a buffer layer 118 may be further formed on the base substrate 110. The buffer layer 118 may have a super-lattice layer structure. The super-lattice layer may have a structure in which thin layers of different materials are alternately stacked. As an example, the buffer layer 118 may have a multi-layer structure in which an insulator layer and a semiconductor layer are alternately grown. The buffer layer 118 as described above may reduce generation of defects due to lattice mismatch between the base substrate 110 and the epi-growth layer 120.

The epi-growth layer 120 may be disposed on the base substrate 110. As an example, the epi-growth layer 120 may include a first nitride layer 122 and a second nitride layer 124 that are sequentially stacked on the base substrate 110. The second nitride layer 124 may be made of a material having a wider energy band gap as compared to the first nitride layer 122. In addition, the second nitride layer 124 may be made of a material having different lattice constants as compared to the first nitride layer 122. For example, the first nitride layer 122 and the second nitride layer 124 may be layers including III-nitride-based materials. More specifically, the first nitride layer 122 may be made of any one of gallium nitride (GaN), aluminum gallium nitride (AlGaN), indium gallium nitride (InGaN), and indium aluminum gallium nitride (InAlGaN), and the second nitride layer 124 may be made of the other one of gallium nitride (GaN), aluminum gallium nitride (AlGaN), indium gallium nitride (InGaN), and indium aluminum gallium nitride (InAlGaN). As an example, the first nitride layer 122 may be a gallium nitride (GaN) layer, and the second nitride layer 124 may be an aluminum gallium nitride (AlGaN) layer.

In the epi-growth layer 120 having the structure as described above, a second-dimensional electron gas (2DEG) may be generated between the first nitride layer 122 and the second nitride layer 124. When the semiconductor device 100 operates, current may flow through the second-dimensional electron gas (2DEG).

The electrode unit 140 may include a Schottky electrode 142 and an ohmic electrode 144. The Schottky electrode 142 may be used as an anode of the nitride-based semiconductor device 100 and the ohmic electrode 144 may be used as a cathode thereof.

The Schottky electrode 142 may be disposed on the epi-growth layer 120 to form a Schottky contact with the second nitride layer 124 of the epi-growth layer 120. The Schottky electrode 142 may have a substantially disk or quadrangular shape. The ohmic electrode 144 may include a first ohmic electrode 144a that is disposed on the upper portion of the epi-growth layer 120 to be spaced apart from the Schottky electrode 142. The first ohmic electrode 144a may form an ohmic contact with the second nitride layer 124. The first ohmic electrode 144a may surround the Schottky electrode 142 or be disposed at both sides of the Schottky electrode 142 based on the Schottky electrode 142.

In addition, the ohmic electrode 144 may further include a second ohmic electrode 144b that is disposed on a lower portion of the base substrate 110. The second ohmic electrode 144b may have a structure to cover the lower surface of the base substrate 110 at a uniform thickness. The second ohmic electrode 144b may form an ohmic contact with the N-type semiconductor layer 112 of the base substrate 110. The second ohmic electrode 144b may be electrically connected to the first ohmic electrode 144a. Therefore, the first and second ohmic electrodes 144a and 144b may be configured such that voltage is simultaneously applied thereto at the time of forward and reverse operations of the nitride-based semiconductor device 100.

As described above, the nitride-based semiconductor device 100 according to an embodiment of the present invention may include the base substrate 110 having the PN junction structure, the epi-growth layer 120 having the second-dimensional electron gas (2DEG), and the electrode unit 140. The PN junction structure of the base substrate 110 may be used as a diode blocking the flow of current from the Schottky electrode 142 to the base substrate 110 when reverse voltage is applied between the Schottky electrode 142 and the ohmic electrode 144 of the electrode unit 140. Therefore, the nitride-based semiconductor device 100 according to the present invention blocks reverse leakage current to improve reverse withstanding voltage of the device, thereby making it possible to improve mass-production efficiency of the nitride-based semiconductor device 100.

In addition, the nitride-based semiconductor device 100 according to an embodiment of the present invention may include the base substrate 110 having the PN junction structure, the epi-growth layer 120 having the second-dimensional electron gas (2DEG), and the electrode unit 140. Therefore, the nitride-based semiconductor device 100 according to the present invention includes the base substrate 110 having the PN junction structure that blocks the reverse leakage current, thereby basically blocking the reverse leakage current and further reducing manufacturing costs of the device as compared to a device using a substrate having a relatively high resistance value.

Hereinafter, a method for manufacturing a nitride-based semiconductor device according to an embodiment of the present invention will be described in detail. Herein, a description overlapping with the nitride-based semiconductor device 100 according to an embodiment of the present invention described above may be omitted or simplified.

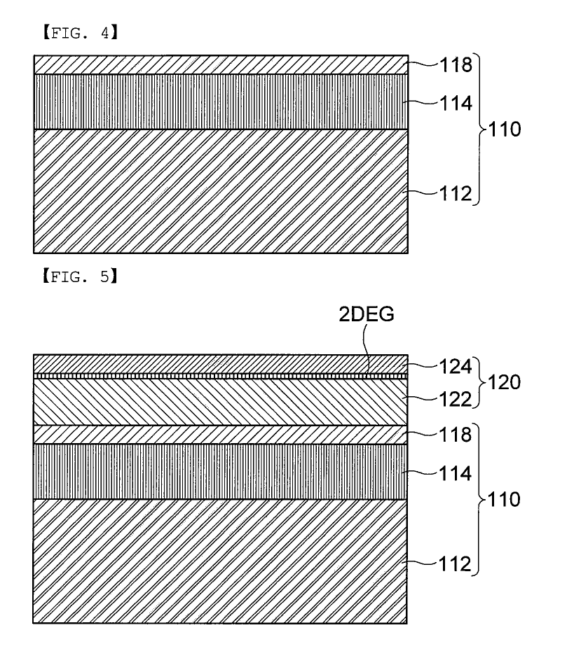

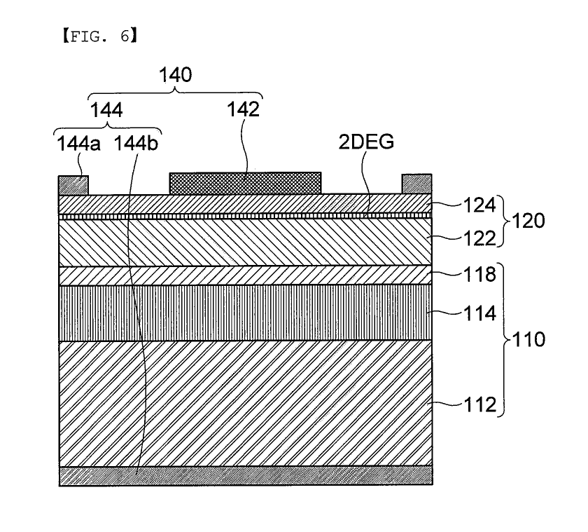

FIG. 3 is a flow chart showing a method for manufacturing a nitride-based semiconductor device according to an embodiment of the present invention. FIGS. 4 to 6 are diagrams for explaining a process for manufacturing a nitride-based semiconductor device according to an embodiment of the present invention.

Referring to FIGS. 3 and 4, a base substrate 110 having a PN junction structure may be prepared (S110). As an example, the preparing the base substrate 110 may include preparing an N-type semiconductor layer 112 that is an N-type silicon substrate having a low resistance value, and forming a P-type semiconductor layer 114 on the N-type silicon substrate 112 by doping the N-type semiconductor layer 112 with P-type impurity ions. Alternatively, the preparing the base substrate 110 may include an N-type semiconductor layer 112 that is an N-type silicon substrate having a low resistance value, and forming a P-type semiconductor layer 114 on the N-type semiconductor layer 112 by using the N-type semiconductor layer 112 as a seed layer.

Meanwhile, the base substrate 110 may use an N-type silicon substrate having a relatively low resistance below 1 k ohm, instead of a silicon substrate, a silicon carbide substrate, a spinel substrate, and a sapphire substrate having a high resistance value, which are expensive. More specifically, a general nitride-based semiconductor device 100 uses any one of a silicon substrate, a silicon carbide substrate, a spinel substrate and sapphire substrate having a high resistance value of approximate 1 k ohm or more, in order to block reverse leakage current. However, the substrate as described above, in particular, the silicon substrate having a high resistance value of 1 k ohm or more, are relatively expensive, such that they may be an important factor to increase manufacturing costs of the nitride-based semiconductor device 100. Therefore, the nitride-based semiconductor device 100 according to the present invention manufactures the base substrate 110 by using the N-type silicon substrate having a relatively low resistance value below 1 k ohm as a base and implanting P-type impurity ions into the N-type silicon substrate, thereby making it possible to reduce manufacturing costs of the nitride-based semiconductor device 100. At this time, the resistance value of the manufactured base substrate 110 may be 1 k ohm or more. In particular, the base substrate 110 has a PN diode structure, thereby making it possible to have a considerably high resistance value in view of the PN diode characteristics.

The present embodiment describes the case in which the base substrate 110 is prepared by doping the N-type silicon substrate with the P-type impurity ions, but the preparing the base substrate 110 may also be made by doping the P-type silicon substrate with the N-type impurity ions.

Meanwhile, the preparing the base substrate 110 may further include forming a buffer layer 118 that covers the P-type semiconductor layer 114. The forming the buffer layer 118 may include forming a super-lattice layer on the P-type semiconductor layer 114. The forming the super-lattice layer may be performed by alternately and repeatedly forming an insulating layer and a semiconductor layer on the P-type semiconductor layer 114.

Referring to FIGS. 3 and 5, an epi-growth layer 120 may be formed on the base substrate 110 by using the base substrate 110 as a seed layer (S120). The forming the epi-growth layer 120 may include forming a first nitride layer 122 on the base substrate 110 and forming a second nitride layer 124 on the first nitride layer 122. As an example, the forming the epi-growth layer 120 may be performed by epitaxially growing the first nitride layer 122 using the base substrate 110 as a seed layer and then epitaxially growing the second nitride layer 124 using the first nitride layer 122 as a seed layer. As an epitaxial growth process for forming the first and second nitride layers 122 and 124, there may be used at least any one of a molecular beam epitaxial growth process, an atomic layer epitaxial growth process, a flow modulation organometallic vapor phase epitaxial growth process, a organometallic vapor phase epitaxial growth process, and a hybrid vapor phase epitaxial growth process. Alternatively, as another example, as a process for forming the first and second nitride layers 122 and 124, there may be used any one of a chemical vapor deposition process and a physical vapor deposition process.

Referring to FIGS. 3 and 6, an electrode unit 140 may be formed (S130). The forming the electrode unit 140 may include forming a Schottky electrode 142 in the center of the upper portion of the epi-growth layer 120, and forming a first ohmic electrode 144a at the edge of the upper portion of the epi-growth layer 120. In addition, the forming the electrode unit 140 may further include forming a second ohmic electrode 144b that covers a lower surface of the base substrate 110.

The forming the electrode unit 140 may include forming a conductive layer that covers a lower portion of the base substrate 110 and an upper portion of the epi-growth layer 120, and selectively patterning the conductive layer that covers the epi-growth layer 120. The forming the conductive layer may be performed by forming a metal layer including at least any one of aluminum (Al), molybdenum (Mo), gold (Au), nickel (Ni), platinum (Pt), titanium (Ti), palladium (Pd), iridium (Ir), rhodium (Rh), cobalt (Co), tungsten (W), tantalum (Ta), copper (Cu), and zinc (Zn) on the lower portion of the base substrate 110 and the upper portion of the epi-growth layer 120.

The metal layer formed in the center of the upper portion of the epi-growth layer 120 may be used as a Schottky electrode 142 by forming a Schottky contact with the second nitride layer 124 of the epi-growth layer 120. The metal layer formed at the edge of the upper portion of the epi-growth layer 120 may be used as a first ohmic electrode 144a by forming an ohmic contact with the second nitride layer 124 of the epi-growth layer 120. The metal layer that covers the lower surface of the base substrate 110 may be used as a second ohmic electrode 114b by forming an ohmic contact with the N-type semiconductor layer 112 of the base substrate 110. The first and second ohmic electrodes 144a and 144b may be electrically connected to each other and be simultaneously applied with voltage at the time of forward and reverse operation of the device 100.

As described above, the method for manufacturing the nitride-based semiconductor device according to the embodiment of the present invention includes the base substrate 110 having the PN junction structure, the epi-growth layer 120 that is epitaxially grown on the upper portion of the base substrate 110, and the electrode unit 140, wherein the PN junction structure may be used as a diode that blocks current from flowing to the base substrate 110 from the Schottky electrode 142 of the electrode unit 140 at the time of reverse operation of the nitride-based semiconductor device. Therefore, the method for manufacturing the nitride-based semiconductor device according to the embodiment of the present invention blocks the reverse leakage current to improve withstanding voltage, thereby making it possible to manufacture the nitride-based semiconductor device with improved mass-production efficiency.

In addition, the method for manufacturing the nitride-based semiconductor device according to the embodiment of the present invention includes the base substrate 110 having the PN junction structure, the epi-growth layer 120 that is epitaxially grown on the upper portion of the base substrate 110, and the electrode unit 140, wherein the base substrate 110 may be formed by doping the N-type silicon substrate having a low resistance value, which is relatively inexpensive, with the P-type impurity ions. Therefore, the method for manufacturing the nitride-based semiconductor device according to the embodiment of the present invention can basically block the reverse leakage current and reduce manufacturing costs of the device as compared to the case when a silicon substrate, a silicon carbide substrate, a spinel substrate, and a sapphire substrate having a high resistance value, which are relatively expensive, are used.

The nitride-based semiconductor device according to the embodiment of the present invention includes the base substrate having a PN junction structure, the epi-growth layer having the 2-dimensional electron gas (2DEG), and the electrode unit, wherein the PN junction structure may be used as a diode that blocks current from flowing to the base substrate from the Schottky electrode when reverse voltage is applied between the Schottky electrode and the ohmic electrode of the electrode unit. Therefore, the nitride-based semiconductor device according to the present invention blocks reverse leakage current to increase reverse withstanding voltage of the device, thereby making it possible to improve mass-production efficiency of the nitride-based semiconductor device.

The nitride-based semiconductor device according to the embodiment of the present invention may include the base substrate having the PN junction structure, the epi-growth layer having the 2-dimensional electron gas (2DEG), and the electrode unit. Therefore, the nitride-based semiconductor device according to the present invention includes the base substrate having the PN junction structure that blocks the reverse leakage current, thereby making it possible to basically block the reverse leakage current and reduce manufacturing costs of the device, as compared to a device using a substrate having a relatively high resistance value.

The method for manufacturing the nitride-based semiconductor device according to the embodiment of the present invention includes the base substrate having the PN junction structure, the epi-growth layer that is epitaxially grown on the upper portion of the base substrate, and the electrode unit, wherein the PN junction structure may be used as a diode that blocks current from flowing to the base substrate from the Schottky electrode of the electrode unit at the time of a reverse operation of the nitride-based semiconductor device. Therefore, the method for manufacturing the nitride-based semiconductor device according to the embodiment of the present invention blocks reverse leakage current to improve withstanding voltage, thereby making it possible to manufacture the nitride-based semiconductor device with improved mass-production efficiency.

The method for manufacturing the nitride-based semiconductor device according to the embodiment of the present invention includes the base substrate having the PN junction structure, the epi-growth layer that is epitaxially grown on the upper portion of the base substrate, and the electrode unit, wherein the base substrate may be formed by doping the N-type silicon substrate having a low resistance value, which is relatively inexpensive, with the P-type impurity ions. Therefore, the method for manufacturing the nitride-based semiconductor device according to the embodiment of the present invention can basically block reverse leakage current and reduce manufacturing costs of the device as compared to the case when a silicon substrate, a silicon carbide substrate, a spinel substrate, and a sapphire substrate having a high resistance value, which are relatively expensive, are used.

The present invention has been described in connection with what is presently considered to be practical exemplary embodiments. Although the exemplary embodiments of the present invention have been described, the present invention may be also used in various other combinations, modifications and environments. In other words, the present invention may be changed or modified within the range of concept of the invention disclosed in the specification, the range equivalent to the disclosure and/or the range of the technology or knowledge in the field to which the present invention pertains. The exemplary embodiments described above have been provided to explain the best state in carrying out the present invention. Therefore, they may be carried out in other states known to the field to which the present invention pertains in using other inventions such as the present invention and also be modified in various forms required in specific application fields and usages of the invention. Therefore, it is to be understood that the invention is not limited to the disclosed embodiments. It is to be understood that other embodiments are also included within the spirit and scope of the appended claims.

What is claimed is:

1. A nitride-based semiconductor device, comprising:
a base substrate having a PN junction structure;
an epi-growth layer disposed on the base substrate; and
an electrode unit disposed on the epi-growth layer.

2. The nitride-based semiconductor device according to claim 1, wherein the PN junction structure includes:
a first type of semiconductor substrate; and
a second type of impurity doped layer formed by doping an upper portion of the semiconductor substrate with second type of impurity ions.

3. The nitride-based semiconductor device according to claim 2, wherein the first type is an N-type, and the second type is a P-type.

4. The nitride-based semiconductor device according to claim 2, wherein the semiconductor substrate is a silicon substrate having resistance value below 1 k ohm, and
the base substrate has a resistance value of 1 k ohm or more.

5. The nitride-based semiconductor device according to claim 1, wherein the PN junction structure is used as a diode that blocks current from flowing from the electrode unit to the base substrate at the time of reverse operation of the nitride-based semiconductor device.

6. The nitride-based semiconductor device according to claim 1, wherein the base substrate further includes a buffer layer that is interposed between the base substrate and the epi-growth layer,
the buffer layer including a super-lattice layer.

7. The nitride-based semiconductor device according to claim 6, wherein the super-lattice layer is formed by alternately stacking an insulator layer and a semiconductor layer.

8. The nitride-based semiconductor device according to claim 1, wherein the epi-growth layer includes:
a first nitride layer disposed on the base substrate; and
a second nitride layer disposed on the first nitride layer and having a wider energy band gap than the first nitride layer,
a 2-dimensional electron gas (2DEG) being generated between the first nitride layer and the second nitride layer.

9. The nitride-based semiconductor device according to claim 1, wherein the electrode unit includes:
a Schottky electrode disposed in the center of the upper portion of the epi-growth layer to form a Schottky contact with the epi-growth layer;
a first ohmic electrode disposed at the edge of the upper portion of the epi-growth layer to form an ohmic contact with the epi-growth layer; and
a second ohmic electrode covering a lower surface of the base substrate.

10. A method for manufacturing a nitride-based semiconductor device, comprising:
preparing a base substrate having a PN junction structure;
forming an epi-growth layer on the base substrate by using the base substrate as a seed layer; and
forming an electrode unit on the epi-growth layer.

11. The method for manufacturing a nitride-based semiconductor device according to claim 10, wherein the preparing the base substrate includes:
preparing a first type of semiconductor substrate; and
doping an upper portion of the semiconductor substrate opposite to the epi-growth layer with second type of impurity ions.

12. The method for manufacturing a nitride-based semiconductor device according to claim 11, wherein the first type is an N-type, and the second type is a P-type.

13. The method for manufacturing a nitride-based semiconductor device according to claim 11, wherein the preparing the semiconductor substrate includes preparing a silicon substrate having a resistance value below 1 k ohm, and
the preparing the base substrate includes a PN junction structure having a resistance value of 1 k ohm or more.

14. The method for manufacturing a nitride-based semiconductor device according to claim 10, wherein the PN junction structure is used as a diode that blocks current from flowing from the electrode unit to the base substrate at the time of reverse operation of the nitride-based semiconductor device.

15. The method for manufacturing a nitride-based semiconductor device according to claim 10, wherein the forming the epi-growth layer includes:
growing a first nitride layer on the base substrate by using the base substrate as a seed layer; and
growing a second nitride layer having a wider energy band gap than the first nitride layer on the first nitride layer by using the first nitride layer as a seed layer,
a 2-dimensional electron gas (2DEG) being generated between the first nitride layer and the second nitride layer.

16. The method for manufacturing a nitride-based semiconductor device according to claim 10, wherein the forming the electrode unit includes:
forming a Schottky electrode in the center of the upper portion of the epi-growth layer;
forming a first ohmic electrode spaced apart from the Schottky electrode at the edge of the upper portion of the epi-growth layer; and
forming a second ohmic electrode covering a lower surface of the base substrate.
